(19) United States
(12) Patent Application Publication
(10) Pub. No.: US 2012/0091575 A1
(43) Pub. Date: Apr. 19, 2012

(54) Semiconductor Package And Method For Making The Same

(76) Inventors: Yi-Shao Lai, Kaohsiung (TW); Tsung-Yueh Tsai, Kaohsiung (TW); Ming-Kun Chen, Kaohsiung (TW); Hsiao-Chuan Chang, Kaohsiung (TW); Ming-Hsiang Cheng, Kaohsiung (TW)

(21) Appl. No.: 12/905,756

(22) Filed: Oct. 15, 2010

(51) Int. Cl. H01L 23/48; H01L 21/50

(52) U.S. Cl. 257/737; 438/121; 257/E23.021; 257/E21.499

(57) ABSTRACT

The present invention relates to a semiconductor package and a method for making the same. The semiconductor package includes a substrate, at least one first chip, a dielectric layer and at least one second chip. The first chip is attached and electrically connected to the substrate. The first chip includes a first active surface and a plurality of first signal coupling pads. The first signal coupling pads are disposed adjacent to the first active surface. The dielectric layer is disposed on the first active surface. The second chip is attached and electrically connected to the substrate by metal bumps. The second chip includes a second active surface and a plurality of second signal coupling pads. The second active surface contacts the dielectric layer. The second signal coupling pads are disposed adjacent to the second active surface, and capacitively coupled to the first signal coupling pads of the first chip, so as to provide proximity communication between the first chip and the second chip. Whereby, the gap between the first signal coupling pads of the first chip and the second signal coupling pads of the second chip is controlled by the thickness of the dielectric layer. Therefore, the mass-production yield of the semiconductor package is increased.

### BACKGROUND OF THE INVENTION

1. Field of the Invention

The present invention relates to a semiconductor package and a method for making the same, and more particularly to a semiconductor package having signal coupling pads and a method for making the same.

2. Description of the Related Art

A new technique referred to as “proximity communication” overcomes the limitations of conductive electrical interconnections by using capacitive coupling to provide communications between two chips. This technique provides higher input/output pads densities than traditional wire-bonding and flip-chip bonding input/output pads (about 100 times greater). To achieve proximity communication, the input/output pads disposed on an active surface of each chip are placed face-to-face, and the gap between the input/output pads of different chips must be controlled with extreme accuracy, which is a big challenge.

Therefore, it is necessary to provide a semiconductor package and a method for making the same to solve the above problems.

### SUMMARY OF THE INVENTION

The present invention is directed to a semiconductor package. The semiconductor package comprises a substrate, at least one first chip, a conductive adhesive, at least one second chip and a dielectric layer. The substrate has a receiving surface and a plurality of substrate pads disposed on the receiving surface. The first chip is attached and electrically connected to the receiving surface of the substrate, and comprises a first active surface, a first back surface, a plurality of first signal coupling pads, a plurality of first chip pads and a redistribution layer. The first back surface faces the receiving surface of the substrate. The first signal coupling pads are disposed adjacent to the first active surface. The first chip pads are disposed adjacent to the first active surface. The redistribution layer extends from the first chip pad to a side surface of the first chip.

The conductive adhesive is disposed between the substrate pad of the substrate and the redistribution layer on the side surface of the first chip. The second chip has a plurality of metal bumps thereon and being attached and electrically connected to the receiving surface of the substrate by the metal bumps. The second chip comprises a second active surface and a plurality of second signal coupling pads. The second active surface faces the receiving surface of the substrate. The second signal coupling pads are disposed adjacent to the second active surface, and capacitively coupled to the first signal coupling pads of the first chip, so as to provide proximity communication between the first chip and the second chip. The dielectric layer is provided between the first active surface and the second active surface.

The present invention is further directed to a method for making a semiconductor package. The method comprises, the following steps: (a) providing a substrate having a receiving surface; (b) providing at least one first chip having a dielectric layer thereon, wherein the first chip has a first active surface, a first back surface and a plurality of first signal coupling pads, and the first signal coupling pads are disposed adjacent to the first active surface, and the dielectric layer is disposed on the first active surface of the first chip; (c) attaching and electrically connecting the first chip to the receiving surface of the substrate, wherein the first back surface of the first chip faces the receiving surface of Ale substrate; and (d) attaching and electrically connecting at least one second chip to the receiving surface of the substrate by a plurality of metal bumps thereon, the second chip has a second active surface and a plurality of second signal coupling pads, the second active surface faces the receiving surface of the substrate and contacts the dielectric layer, the second signal coupling pads are disposed adjacent to the second active surface and capacitively coupled to the first signal coupling pads of the first chip, so as to provide proximity communication between the first chip and the second chip.

The present invention is further directed to a method for making a semiconductor package. The method comprises the following steps: (a) providing a substrate having a receiving surface; (b) attaching and electrically connecting at least one first chip to the receiving surface of the substrate, wherein the first chip has a first active surface, a first back surface and a plurality of first signal coupling pads, the first back surface faces the receiving surface of the substrate, and the first signal coupling pads are disposed adjacent to the first active surface; and (c) providing at least one second chip having a dielectric layer thereon, wherein the second chip has a second active surface, a plurality of metal bumps and a plurality of second signal coupling pads, the second signal coupling pads and the metal bumps are disposed adjacent to the second active surface, and the dielectric layer is disposed on the second active surface of the second chip; and (d) attaching and electrically connecting the second chip to the receiving surface of the substrate by the metal bumps, the second active surface faces the receiving surface of the substrate, the dielectric layer contacts the first active surface of the first chip, the second signal coupling pads are capacitively coupled to the first signal coupling pads of the first chip, so as to provide proximity communication between the first chip and the second chip.

Whereby, the gap between the first signal coupling pads of the first chip and the second signal coupling pads of the second chip is controlled by the thickness of the dielectric layer. Therefore, the mass-production yield of the semiconductor package is increased.

### BRIEF DESCRIPTION OF THE DRAWINGS

FIGS. 1 to 5 are schematic views of a method for making a semiconductor package according to a first embodiment of the present invention; and

FIGS. 6 to 9 are schematic views of a method for making a semiconductor package according to a second embodiment of the present invention.

### DETAILED DESCRIPTION OF THE INVENTION

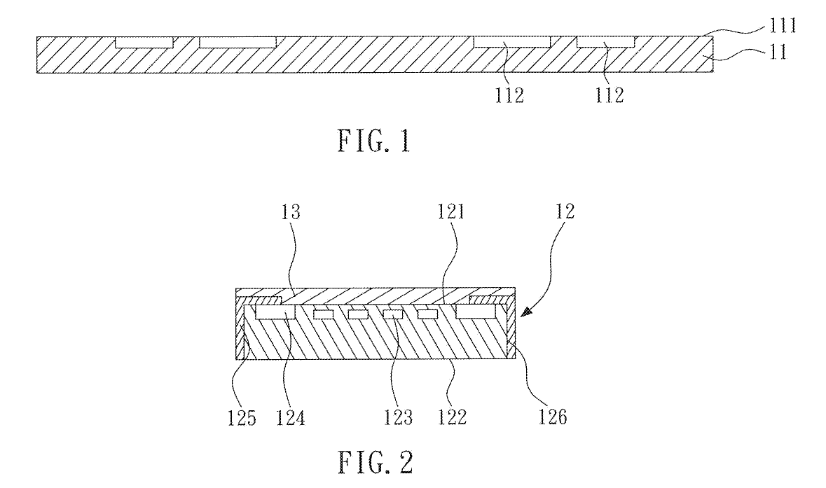

FIGS. 1 to 5 show schematic views of a method for making a semiconductor package according to a first embodiment of the present invention. As shown in FIG. 1, a substrate 11 is provided. The substrate 11 has a receiving surface 111. In the embodiment, the substrate 11 further comprises a plurality of substrate pads 112 disposed on the receiving surface 111 of the substrate 11.

As shown in FIG. 2, at least one first chip 12 and a dielectric layer 13 are provided. The first chip 12 has a first active surface 121, a first back surface 122 and a plurality of first signal coupling pads 123. In the embodiment, the first chip 12 further comprises a plurality of first chip pads 124 and a redistribution layer 125. The first signal coupling pads 123 are disposed adjacent to the first active surface 121. The dielectric layer 13 is disposed on the first active surface 121 of the first chip 12. The first chip pads 124 are disposed adjacent to the first active surface 121. The redistribution layer 125 extends from the first chip pad 124 to a side surface 126 of the first chip 12. In the embodiment, the dielectric layer 13 is a photo-resist layer. In other embodiment, the dielectric layer 13 may be a passivation layer.

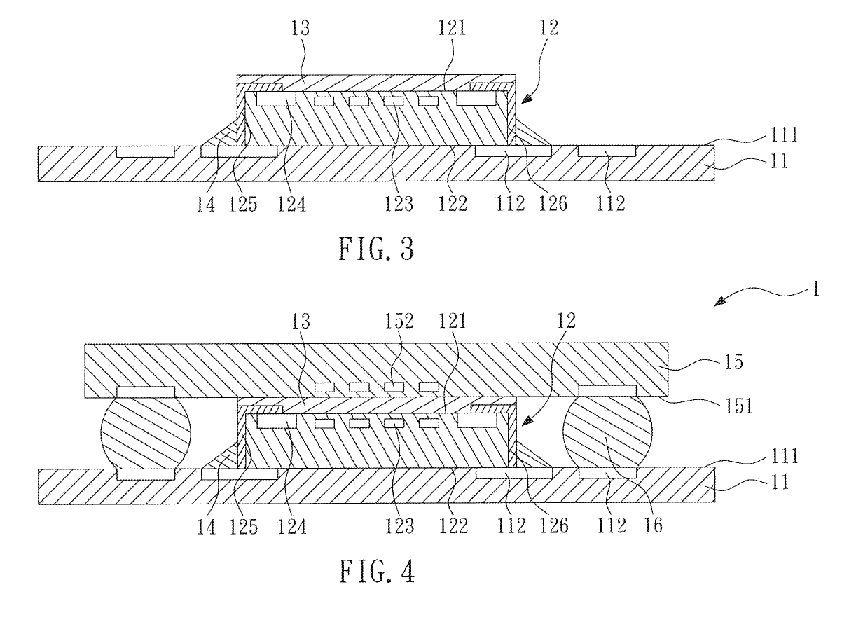

As shown in FIG. 3, the first chip 12 is attached and electrically connected to the receiving surface 111 of the substrate 11 via a conductive adhesive 14 disposed between the substrate pad 112 of the substrate 11 and the redistribution layer 125 on the side surface of the first chip 12. The first back surface 122 of the first chip 12 faces the receiving surface 111 of the substrate 11. In the embodiment, the conductive adhesive 14 is a solder paste. More particularly, the solder paste can be disposed on the substrate 11 before or after disposing the first chip 12, and then a reflow process is conducted. In other embodiment, the conductive adhesive 14 may be an anisotropic conductive film (ACF) or an anisotropic conductive paste (ACP).

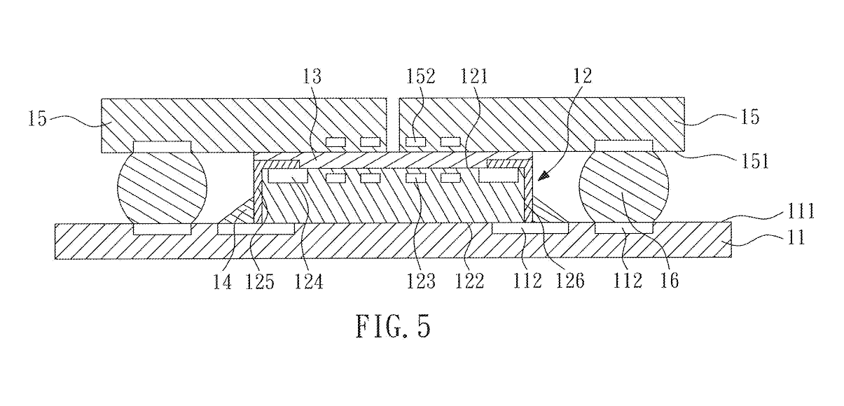

As shown in FIG. 4, at least one second chip 15 is attached and electrically connected to the receiving surface 111 of the substrate 11 by a plurality of metal bumps 16, and the semiconductor package 1 is formed. The second chip 15 has a second active surface 151, the metal bumps 16 and a plurality of second signal coupling pads 152. The second active surface 151 faces the receiving surface 111 of the substrate 11 and contacts the dielectric layer 13. The second signal coupling pads 152 and the metal bumps 16 are disposed adjacent to the second active surface 151. The second signal coupling pads 152 are capacitively coupled to the first signal coupling pads 123 of the first chip 12, so as to provide proximity communication between the first chip 12 and the second chip 15. The gap between the first signal coupling pads 123 and the second signal coupling pads 152 is controlled by the thickness of the dielectric layer 13. The thickness of dielectric layer 13 is less than about 20 μm. In the embodiment, the number of the second chip 15 is one, the size of the second chip 15 is larger than that of the first chip 12, and the second signal coupling pads 152 are disposed at a center portion of the second chip 15. In other embodiment, as shown in FIG. 5, the number of the second chip 15 may be two, so that the metal bumps 16 are provided on one side of each second chip 15, and the second signal coupling pads 152 are disposed on the other side of each second chip 15.

FIG. 4 shows a cross-sectional view of a semiconductor package according to the first embodiment of the present invention. The semiconductor package 1 comprises a substrate 11, at least one first chip 12, a dielectric layer 13, at least one second chip 15 and a conductive adhesive 14. The substrate 11 has a receiving surface 111. In the embodiment, the substrate 11 further comprises a plurality of substrate pads 112 disposed on the receiving surface 111 of the substrate 11.

The first chip 12 is attached and electrically connected to the receiving surface 111 of the substrate 11. The first chip 12 comprises a first active surface 121, a first back surface 122, a plurality of first signal coupling pads 123 a plurality of first chip pads 124 and a redistribution layer 125. The first back surface 122 faces the receiving surface 111 of the substrate 11. The first signal coupling pads 123 are disposed adjacent to the first active surface 121. The first chip pads 124 are disposed adjacent to the first active surface 121 and electrically connected to the substrate pads 112, and more particularly, at an edge of the first chip 12. The redistribution layer 125 extends to a side surface 126 of the first chip 12 for connecting the first chip pads 124 and the substrate pads 112.

The second chip 15 is attached and electrically connected to the receiving surface 111 of the substrate 11 by the metal bumps 16. The second chip 15 comprises a second active surface 151 and a plurality of second signal coupling pads 152. The second active surface 151 faces the receiving surface 111 of the substrate 11. The second signal coupling pads 152 and the metal bumps 16 are disposed adjacent to the second active surface 151. The second signal coupling pads 152 are capacitively coupled to the first signal coupling pads 123 of the first chip 12, so as to provide proximity communication between the first chip 12 and the second chip 15.

The dielectric layer 13 is provided between the first active surface 121 and the second active surface 151. In the embodiment, the dielectric layer 13 is a photo-resist layer. In other embodiment, the dielectric layer 13 may be a passivation layer. The conductive adhesive 14 is disposed between the substrate pad 112 of the substrate 11 and the redistribution layer 125 on the side surface 126 of the first chip 12, so as to electrically connect the substrate 11 and the first chip 12. In the embodiment, the conductive adhesive 14 is a solder paste. In other embodiment, the conductive adhesive 14 may be an anisotropic conductive film (ACF) or an anisotropic conductive paste (ACP).

Whereby, the gap between the first signal coupling pads 123 of the first chip 12 and the second signal coupling pads 152 of the second chip 15 is controlled by the thickness of the dielectric layer 13 rather than by the metal bumps 16. Use of the dielectric layer 13 would allow immediate and more accurate control of the gap between the first signal coupling pads 123 and the second signal coupling pads 152 under 20 μm. That is, the thickness of dielectric layer 13 is less than about 20 μm. It is to be noted that the metal bumps 16 are not used to control the gap between the first signal coupling pads 123 and the second signal coupling pads 152. In the embodiment, the number of the second chip 15 is one, the size of the second chip 15 is larger than that of the first chip 12, and the second signal coupling pads 152 are disposed at a center portion of the second chip 15. In other embodiment, as shown in FIG. 5, the number of the second chip 15 may be two, so that the metal bumps 16 are provided on one side of each second chip 15, and the second signal coupling pads 152 are disposed on the other side of each second chip 15.

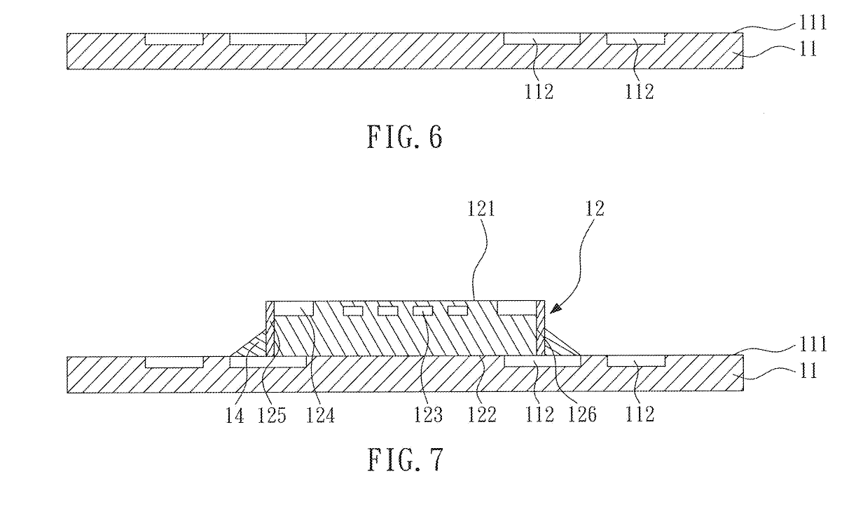

FIGS. 6 to 9 show schematic views of a method for making a semiconductor package according to a second embodiment of the present invention. The method according to the second embodiment is substantially the same as the method (FIGS. 1 to 5) according to the first embodiment, and the same elements are designated by the same reference numbers. The difference between the method according to the second embodiment and the method (FIGS. 1 to 5) according to the first embodiment is described as below. As shown in FIG. 6, the substrate 11 is provided. As shown in FIG. 7, the first chip 12 is attached and electrically connected to the receiving surface 111 of the substrate 11. In the embodiment, the first chip pads 124 are exposed to the side surface 126 of the first chip 12 after a cutting process (part of each of the first chip pads 124 is disposed on a cutting line and then is cut off). Therefore, the redistribution layer 125 is only disposed on the side surface 126 of the first chip 12 for connecting the first chip pads 124 and the substrate pads 112.

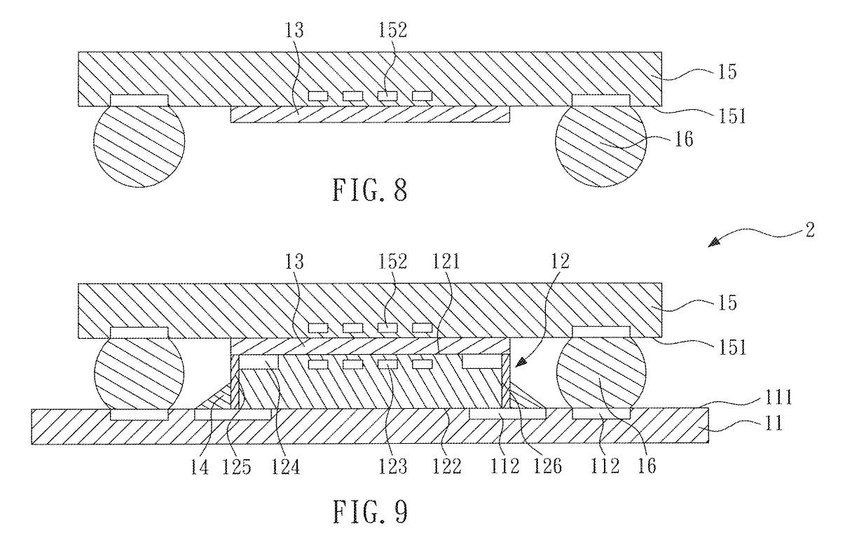

As shown in FIG. 8, the second chip 15 and the dielectric layer 13 are provided. In the embodiment, the dielectric layer 13 is disposed on the second active surface 151 of the second chip 15. As shown in FIG. 9, the second chip 15 is attached and electrically connected to the receiving surface 111 of the substrate 11 by a the metal bumps 16. In the embodiment, the dielectric layer 13 contacts the first active surface 121 of the first chip 12.

FIG. 9 shows a cross-sectional view of a semiconductor package according to the second embodiment of the present invention. The semiconductor package 2 according to the second embodiment is substantially the same as the semiconductor package 1 according to the first embodiment (FIG. 4), and the same elements are designated by the same reference numbers. In the embodiment, the first chip pads 124 are exposed to the side surface 126 of the first chip 12. The redistribution layer 125 is only disposed on the side surface 126 of the first chip 12.

It should be noted that the first chip 12 and the second chip 15 communicate with each other through proximity communication between the first signal coupling pads 123 and the second signal coupling pads 152, instead of direct electrical connections; however, electrical power or ground is transmitted between the first chip 12 and the second chip 15 through direct electrical connections (the metal bumps 16).

In order to achieve the function of proximity communication, part of the first chip 12 and the second chip 15 are placed face-to-face in a manner that aligns the transmitter circuit with the receiver circuit in extremely close proximity, for example, with only microns of separation between them. The signals between the transmitter circuit and the receiver circuit may be transmitted by inductive or capacitive coupling with low overall communication cost.

Take transmission by capacitive coupling for example. The first signal coupling pads 123 of the first chip 12 and the second signal coupling pads 152 of the second chip 15 are aligned with each other. Since the first signal coupling pads 123 and the second signal coupling pads 152 are not in physical contact with each other, there are capacitances between the first signal coupling pads 123 of the first chip 12 and the second signal coupling pads 152 of the second chip 15. It is this capacitive coupling that provides signal paths between the first chip 12 and the second chip 15. Changes in the electrical potential of the first signal coupling pads 123 of the first chip 12 cause corresponding changes in the electrical potential of the corresponding second signal coupling pads 152 of the second chip 15. Suitable drivers of the transmitter circuit and sensing circuits of the receiver circuit in the first chip 12 and the second chip 15 make communication through this small capacitance possible.

In the present invention, the gap between the first signal coupling pads 123 of the first chip 12 and the second signal coupling pads 152 of the second chip 15 is controlled by the thickness of the dielectric layer 13. Therefore, such control is very accurate, and the mass-production yield of the semiconductor packages 1, 2 is increased.

While several embodiments of the present invention have been illustrated and described, various modifications and improvements can be made by those skilled in the art. The embodiments of the present invention are therefore described in an illustrative but not restrictive sense. It is intended that the present invention should not be limited to the particular forms as illustrated, and that all modifications which maintain the spirit and scope of the present invention are within the scope defined by the appended claims.

What is claimed is:

1. A semiconductor package, comprising:
a substrate, having a receiving surface and a plurality of substrate pads disposed on the receiving surface;
at least one first chip, attached and electrically connected to the receiving surface of the substrate, the first chip comprising:
a first active surface;
a first back surface, facing the receiving surface of the substrate; and
a plurality of first signal coupling pads, disposed adjacent to the first active surface;
a plurality of first chip pads, disposed adjacent to the first active surface; and
a redistribution layer, extending from the first chip pad to a side surface of the first chip;
a conductive adhesive, disposed between the substrate pad of the substrate and the redistribution layer on the side surface of the first chip;
at least one second chip having a plurality of metal bumps thereon and being attached and electrically connected to the receiving surface of the substrate by the metal bumps, the second chip comprising:
a second active surface, facing the receiving surface of the substrate; and
a plurality of second signal coupling pads, disposed adjacent to the second active surface, and capacitively coupled to the first signal coupling pads of the first chip, so as to provide proximity communication between the first chip and the second chip; and
a dielectric layer provided between the first active surface and the second active surface.

2. The semiconductor package as claimed in claim 1, wherein the dielectric layer is a passivation layer or a photo-resist layer.

3. The semiconductor package as claimed in claim 1, wherein the thickness of dielectric layer is less than about 20 μm.

4. The semiconductor package as claimed in claim 1, wherein the number of the second chip is one, the size of the second chip is larger than that of the first chip, and the second signal coupling pads are disposed at a center portion of the second chip.

5. The semiconductor package as claimed in claim 1, wherein the number of the second chip is two, the metal bumps are provided on one side of each second chip, and the second signal coupling pads are disposed on the other side of each second chip.

6. A method for making a semiconductor package, which comprises:
(a) providing a substrate having a receiving surface;
(b) providing at least one first chip having a dielectric layer thereon, wherein the first chip has a first active surface, a first back surface and a plurality of first signal coupling pads, and the first signal coupling pads are disposed adjacent to the first active surface, and the dielectric layer is disposed on the first active surface of the first chip;
(c) attaching and electrically connecting the first chip to the receiving surface of the substrate, wherein the first back surface of the first chip faces the receiving surface of the substrate; and
(d) attaching and electrically connecting at least one second chip to the receiving surface of the substrate by a plurality of metal bumps thereon, the second chip has a second active surface and a plurality of second signal coupling pads, the second active surface faces the receiving surface of the substrate and contacts the dielectric layer, the second signal coupling pads are disposed adjacent to the second active surface and capacitively coupled to the first signal coupling pads of the first chip, so as to provide proximity communication between the first chip and the second chip.

7. The method as claimed in claim 6, wherein the substrate further to comprises a plurality of substrate pads disposed on the receiving surface of the substrate, the first chip further comprises a plurality of first chip pads disposed adjacent to the first active surface, and a redistribution layer extending from the first chip pad to a side surface of the first chip, and the step (c) further comprises forming a conductive adhesive between the substrate pad of the substrate and the redistribution layer on the side surface of the first chip.

8. The method as claimed in claim 6, wherein in step (b), the dielectric layer is a passivation layer or a photo-resist layer.

9. The method as claimed in claim 6, wherein the thickness of the dielectric layer is less than about 20 μm.

10. The method as claimed in claim 6, wherein in step (d), the number of the second chip is one, the size of the second chip is larger than that of the first chip, and the second signal coupling pads are disposed at a center portion of the second chip.

11. The method as claimed in claim 6, wherein in step (d), the number of the second chip is two, the metal bumps are provided on one side of each second chip, and the second signal coupling pads are disposed on the other side of each second chip.

12. A method for making a semiconductor package, which comprises:
(a) providing a substrate having a receiving surface;
(b) attaching and electrically connecting at least one first chip to the receiving surface of the substrate, wherein the first chip has a first active surface, a first back surface and a plurality of first signal coupling pads, the first back surface faces the receiving surface of the substrate, and the first signal coupling pads are disposed adjacent to the first active surface; and
(c) providing at least one second chip having a dielectric layer thereon, wherein the second chip has a second active surface, a plurality of metal bumps and a plurality of second signal coupling pads, the second signal coupling pads and the metal bumps are disposed adjacent to the second active surface, and the dielectric layer is disposed on the second active surface of the second chip; and
(d) attaching and electrically connecting the second chip to the receiving surface of the substrate by the metal bumps, the second active surface faces the receiving surface of the substrate, the dielectric layer contacts the first active surface of the first chip, the second signal coupling pads are capacitively coupled to the first signal coupling pads of the first chip, so as to provide proximity communication between the first chip and the second chip.

13. The method as claimed in claim 12, wherein the substrate further comprises a plurality of substrate pads disposed on the receiving surface of the substrate, the first chip further comprises a plurality of first chip pads disposed adjacent to the first active surface and a redistribution layer extending from the first chip pad to a side surface of the first chip, and the step (c) further comprises forming a conductive adhesive between the substrate pad of the substrate and the redistribution layer on the side surface of the first chip.

14. The method as claimed in claim 12, wherein in step (c), the dielectric layer is a passivation layer or a photo-resist layer.

15. The method as claimed in claim 12, wherein the thickness of the dielectric layer is less than about 20 μm.

16. The method as claimed in claim 12, wherein in step (d), the number of the second chip is one, the size of the second chip is larger than that of the first chip, and the second signal coupling pads are disposed at a center portion of the second chip.

17. The method as claimed in claim 12, wherein in step (d), the number of the second chip is two, the metal bumps are provided on one side of each second chip, and the second signal coupling pads are disposed on the other side of each second chip.
